(19) United States
(12) Patent Application Publication
(10) Pub. No.: US 2014/0131675 A1
(43) Pub. Date: May 15, 2014

(54) LIGHT-EXTRACTION ELEMENT AND LIGHT-EMITTING DEVICE

(71) Applicant: Industrial Technology Research Institute, Hsinchu (TW)

(72) Inventors: Pei-Chi CHIEN, Zhudong Township (TW); Ping-Chen CHEN, Taipei City (TW)

(21) Appl. No.: 13/923,591

(22) Filed: Jun. 21, 2013

(30) Foreign Application Priority Data
Nov. 13, 2012 (TW) 101142144

(51) Int. Cl. H01L 51/52; F21V 5/00

(52) U.S. Cl. CPC H01L 51/5275; F21V 5/002
USPC 257/40; 362/326

(57) ABSTRACT

The invention provides a light-extraction element, comprising a light-diffusion layer which including a resin; a first particle with a single refractive index; and a second particle with two different refractive indices, wherein the second particle is a hollow particle or a core-shell particle, wherein the refractive index of the core is different from that of the shell. The invention also provides a light-emitting device, including a pair of electrodes composed of an anode and a cathode; an organic light-emitting unit disposed between the pair of electrodes, wherein the organic light-emitting unit includes a light-emitting layer; and a light-extraction element which is disposed on a light-emitting surface of the light-emitting device.

### CROSS REFERENCE TO RELATED APPLICATIONS

This application is based upon and claims the benefit of priority from the prior Taiwan Patent Application No. 101142144, filed on Nov. 13, 2012, the entire contents of which are incorporated herein by reference.

### BACKGROUND

1. Technical Field

The technical field relates to a light-extraction element and light-emitting device.

2. Related Art

The light-emitting element of the organic light-emitting diode (OLED) is generally composed of glass substrates, conductive electrodes made of indium tin oxide (ITO), and an organic light-emitting layer. No matter whether the type of OLED is “top-emitting” or “bottom-emitting”, the large difference between the refractive indices of the materials used in the components results in reflection on the interface. This reflection in OLEDs may cause a low efficiency of light extraction. According to the studies, in general OLEDs, almost a 70-80% loss of light, which cannot be guided outside the elements, is the resulted of the reflection on the interface. Since the difference of the refractive indices of the materials used in OLEDs is too large, the total light-extraction efficiency may be improved by selecting the materials of the internal components of OLEDs or changing the structure thereof. However, by altering materials and structures, the accompanying change in the manufacturing process brings a greater challenge to the development of OLEDs.

So far, the external light extraction diffusion layer of OLEDs is generally composed of solid organic particles or inorganic particles with a high refractive index, and accomplishes the diffusion effects by light scattering. However, the effect of light extraction is unsatisfactory.

Previous studies have demonstrated that a diffusion layer comprising microlens or solid inorganic particles as a light-extraction film, or forming a scattering layer using particles, ultrafine particles, and resin. Since the particles are surrounded by a high concentration of ultrafine particles with a large difference of refractive indexes, a good light-extraction efficiency can be obtained. However, the effect of reducing the color shift is limited. In addition, it has also been reported that color shift can be reduced by first coating a scattering layer (a particle with a high refractive index, the particle size being about 0.2-1 μm) and then a light condenser layer (the refractive index of the particle being about 1.4-1.5, and the particle size being about 3-10 μm) on the transparent resin substrate. Although the combination of two coatings as a light-extraction layer can reduce the color shift, the process is more complicated. It is known that forming the scattering layer using hollow particles can significantly reduce the color shift; however, although the light-extraction efficiency of the center viewing angle is good, the total light-extraction efficiency is worse since the light-extraction efficiency decreases with an increase in the viewing angle.

Therefore, a method for improving the light-extraction efficiency of the light-emitting element of OLEDs is required.

### SUMMARY

A detailed description is given in the following embodiments with reference to the accompanying drawings.

According to an embodiment, the disclosure provides a light-extraction element, including a light-diffusion layer, which comprises a resin; a first particle with a single refractive index; and a second particle with two different refractive indices, wherein the second particle is a hollow particle or a core-shell particle, having different refractive indices between core and shell.

In accordance with another embodiment, the disclosure also provides a light-emitting device, including a pair of electrodes composed of an anode and a cathode; an organic light-emitting unit disposed between the pair of electrodes, wherein the organic light-emitting unit includes a light-emitting layer; and a light-extraction element disposed on a light-extraction surface of the light-emitting device.

### BRIEF DESCRIPTION OF DRAWINGS

The disclosure can be more fully understood by reading the subsequent detailed description and examples with references made to the accompanying drawings, wherein:

FIG. 1 is a schematic view of a light-extraction element according to an embodiment.

FIG. 2 is a cross-sectional view of a light-emitting device comprising a light-extraction element according to an embodiment.

FIG. 3A is a cross-sectional view of a self-made hollow acrylic particle P50 according to an embodiment.

FIG. 3B shows a particle size distribution of the self-made hollow acrylic particle P50 according to some embodiments of the disclosure.

FIG. 4 shows the brightness change of the light-extraction element including different particle compositions where the materials of the light-diffusion layer are composed of the solid particle SBX6 and the hollow particle P50; and

FIG. 5 shows the brightness change of the light-extraction element including different particle compositions where the materials of the light-diffusion layer are composed of the solid particle SBX17 and the hollow particle P50.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

A light-extraction element suitable for use in a light-emitting device is provided. Scattering occurs due to the collision of lights when they enter the light-diffusion layer, which results in a change of the angle of light propagation, thereby enhancing the light-extraction efficiency of the light source. The present disclosure enhances the light-extraction efficiency of the light-emitting device, for example, an organic light-emitting diode (OLED), in a simple and cost-effective manner.

The light-diffusion layer of the discussion is made of a resin and diffusion materials, including a first particle with a single refractive index as well as a second particle with two different refractive indices. Scattering can be caused not only by the difference of the refractive indices between the resin and the particles, but also by the difference of the refractive indices between the particle material and the pores within the particles, or the difference of the refractive indices between the different materials of the particles themselves. When the lights pass through the interior of the particles, by entering media with different refractive indices several times, the resulting scattering can not only significantly enhance the light-extraction efficiency, but also reduce or even eliminate the color shift of OLEDs at a wide viewing angle.

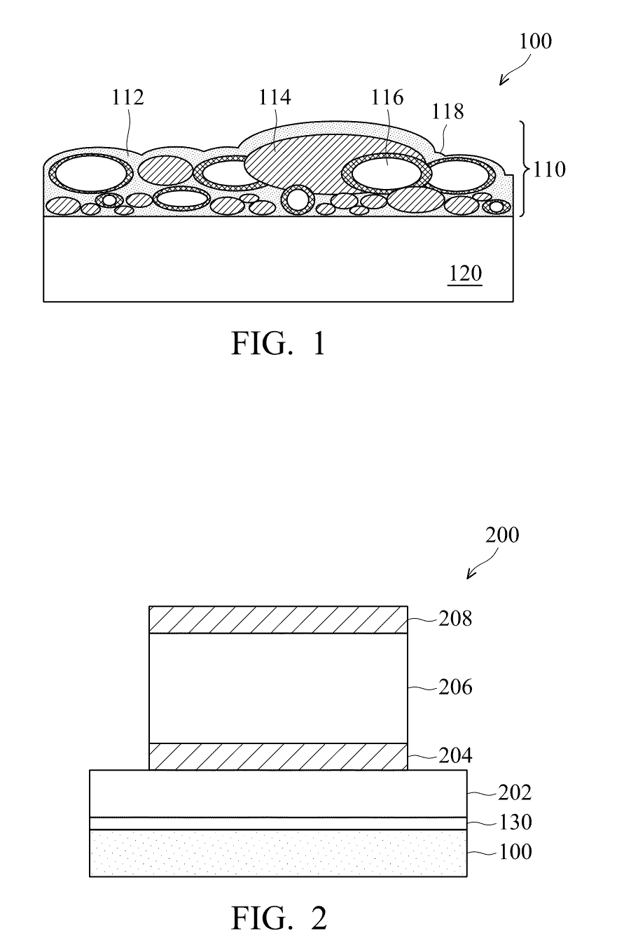

FIG. 1 is a schematic view of a light-extraction element 100 according to an embodiment of the disclosure. The light-extraction element 100 includes a light-diffusion layer 110 which includes a resin 112, a first particle 114 with a single refractive index, and a second particle 116 with two different refractive indices, which are dispersed in the resin 112. The first particle 114 is a solid particle. The second particle 116 may be a hollow particle with an internal refractive index equal to 1 (air) and a refractive index of the shell greater than 1. Alternatively, the second particle 116 may also be a core-shell particle, wherein the refractive index of the core is different from that of the shell. In addition, the second particle 116 may further include a single-hollow particle, a multi-hollow particle, or a particle with two or more refractive indices. To achieve an excellent light scattering phenomenon, the refractive index of the first particle 114 is different from that of the resin 112, and the refractive index of the shell of the second particle 116 (the hollow particle or the core-shell particle) is different from that of the resin 112.

The hollow particle mentioned above can be formed by a surfactant reverse micelles swelling method. Different monomers (such as acrylic monomers), an emulsifier (such as Tween 80 and span 80), and an initiator (such as benzyl peroxide) were uniformly mixed and added into an aqueous system containing a dispersant and an emulsifier for reaction at 70-80° C. for about 20 hours to form the hollow particle.

The core-shell particle mentioned above may be, for example, a particle with a refractive index of the core greater than that of the shell. For example, the particle may be formed by a two-step microemulsion polymerization according to Advanced Functional Materials, Volume 15, Issue 3. The material of the core and the shell of the particle may independently be, for example, polypyrrole (PPy), poly methyl methacrylate (PMMA), etc. depending on the desired difference of the refractive indices.

Alternatively, the core-shell particle may be, for example, a particle with a refractive index of the core less than that of the shell. For example, the particle may be formed by dispersive polymerization, seed dispersive polymerization, or mechanical fusion system according to Colloid & Polymer Science Volume 277, Number 12 (1999), 1142-1151, Colloid & Polymer Science Volume 277, Number 9 (1999), 875-880, or Journal of Materials Science, Volume 37 (2002), 2317-2321. The material of the core and the shell of the particle may independently be, for example, silica, polystyrene, poly methyl methacrylate (PMMA), Al₂O₃, etc. depending on the desired difference of the refractive indices.

The material of each of the first particle 114 and the second particle 116 may independently include polystyrene, polymethacrylic ester, copolymers of methyl methacrylate and styrene, polycarbonate, polyethylene, silicone resin, calcium carbonate, silicon dioxide, titanium dioxide, or combinations thereof. Each of the first particle 114 and the second particle 116 may independently have a particle size distribution between about 0.01 μm and about 150 μm, for example, between about 0.01 μm to about 60 μm, or about 0.01 μm to about 100 μm. It should be noted that the first particle 114 and the second particle 116 is not limited to a spherical shape as shown in the drawings. Each of the first particle 114 and the second particle 116 may independently be a spherical particle, a hemispherical particle, a rod-like particle, a lens-like particle, an irregular-shaped particle, or combinations thereof. The improved light extraction can be achieved regardless of the particle shape as long as the particles possess the described refractive index.

The resin 112 may include a thermoplastic resin, a thermo-curable resin, a light-curable resin, or combinations thereof. The ratio of the total weight of the first particle 114 and the second particle 116 to the weight of resin 112 is between about 1/10 to about 10/1, or between about ⅙ to about 6/1. In one embodiment, the resin 112 covers the first particle 114 and the second particle 116 and forms an irregular top surface 118 to enhance the light-extraction efficiency. In another embodiment, the resin 112 may also form a flat top surface 118.

Referring to FIG. 1, the light-diffusion layer 110 may further include an additive to adjust the degree of uniformity and dispersion. The additive may include one or more non-ionic dispersants such as Tween-20, Tween-60, Tween-800, one or more surfactants such as fluorinated surfactants such as FC4432, FC430, or a combination dispersant and surfactant thereof. The additive is present in the amount of about 0.005 and about 15 wt %, based on the total weight of the first particle 114 and the second particle 116.

Referring to FIG. 1, the light-extraction element 100 may further include a substrate 120 may include, for example, polyethylene terephthalate (PET), polyethylene naphthalate (PEN), etc., wherein the light-diffusion layer 110 is disposed on the substrate 120. The light-extraction element 100 may further include an adhesion layer 130 which is disposed on an opposite surface of the substrate 120 relative to the light-diffusion layer 110 to adhere the light-extraction element 100 on the light-emitting surface of the OLED device. The adhesion layer 130 may include, for example, a transparent glue including polypropylene, a thermo-curable glue, or an ultraviolet light-curable glue.

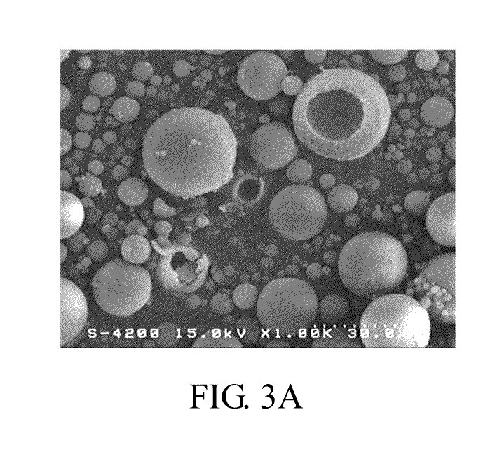

FIG. 2 is a cross-sectional view of a light-emitting device 200 according to an embodiment of the disclosure. The light-emitting device 200 includes a substrate 202 on which a lower electrode 204, an organic light-emitting unit 206, and an upper electrode 208 are sequentially stacked. The above mentioned light-extraction element 100 is disposed on the light-emitting surface of the light-emitting device 200 by the adhesion layer 130. Although the light-emitting device 200 as shown in FIG. 2 is bottom-emitting type, it may be a top-emitting type, wherein a substrate 202, an adhesion layer 130, and a light-extraction element 100 may be sequentially formed on the upper electrode 208. Alternatively, the light-emitting device 200 may also be a double-emitting type, wherein a substrate 202, an adhesion layer 130, and a light-extraction element 100 may be sequentially formed on both of the two light-emitting surfaces of the light-emitting device 200, respectively. The substrate 202 may be a transparent substrate such as a glass substrate, plastic substrate, or semiconductor substrate. The material of the lower electrode 204 and the upper electrode 208 may be, for example, Li, Mg, Ca, Al, Ag, In, Au, Wu, Ni, Pt, Cu, indium tin oxide (ITO), indium zinc oxide (IZO), zinc aluminum oxide (AZO), ZnO, or combinations thereof. Moreover, at least one of the lower electrode 204 and the upper electrode 208 has a light-transparency property. The organic light-emitting unit 206 is disposed between the pair of electrodes, wherein the organic light-emitting unit 206 includes at least one light-emitting layer. The organic light-emitting unit 206 may further include a hole injection layer, a hole transport layer, an electron transport layer, an electron injection layer, or other layers as are well known in the art. The configuration of the above layers is well known by those skilled in the art, and is not described herein for simplicity.

Without changing the process of OLEDs, the embodiments of the disclosure reduce the reflectivity of the interface by adding a structural layer on the surface of OLEDs to enhance the light-extraction efficiency and reduce the color shift at the same time.

[Preparation Examples]

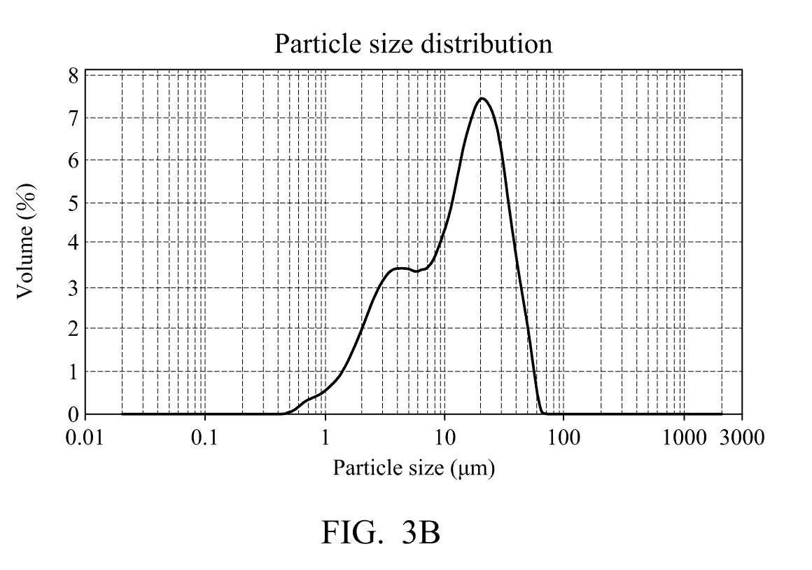

Hollow particles were prepared by using a surfactant reverse micelles swelling method. Acrylic monomers ethylene glycol dimethacrylate (EGDMA) and glycidyl methacrylate (GMA) (weight ratio of 1:1), emulsifiers of Tween 80 (⅛ weight of the monomers), span 80 (⅛ weight of the monomers), a solvent of 4-methyl-2-pentanol ( 1/10 weight of the monomers), and an initiator of benzyl peroxide (4% weight of the monomers) were uniformly mixed and added into an aqueous system containing a dispersant of polyvinyl alcohol (PVA)(¼ weight of the monomers) and an emulsifier of sodium dodecyl sulfate (SDS) (0.4% weight of the monomers), and sodium sulfate (0.5% weight of the monomers). The above mixture was stirred for 1 hour at a stirring speed of 160 rpm under nitrogen atmosphere and then heated to 75° C. for reaction for 20 hours at the same stirring speed to form the hollow particles. Depending on different stirring speeds and ratios of dispersants, hollow particles with various sizes can be formed. For example, the particle size distribution of hollow particles P50 was between about 0.01 μm and about 60 μm, the particle size distribution of hollow particles P90 was between about 0.01 μm and about 90 μm, and the particle size distribution of hollow particles P150 was between about 0.01 μm and about 150 μm. FIG. 3A and FIG. 3B respectively show a cross-sectional view and a particle size distribution of the hollow acrylic particles P50.

[Examples and Comparative Examples]

3M fluorinated surfactant (FC4432), toluene, and isopropanol (IPA) with several kinds of solid particles and particles containing pores were stirred and then a thermo-curable acrylic modified resin (MCL_{—}1; a self-made acrylic resin formed by solvent polymerization. 30% weight ratio of lauryl acrylate monomer and 70% weight ratio of methyl methacrylate monomer were heated in toluene solvent at 90° C. for polymerization for 10 hours) (the refractive index of MCL_{—}1 was 1.48) was added and stirred. The weight ratio of resin/toluene/isopropanol was 4/9/2. The weight ratio of the surfactant (FC4432)/total particles was 0.042. The weight ratio of the total particles/resin was 0.83.

[Materials of the Particles]

Solid Particles

(1) Solid styrene particles SBX6 (SEKISUI CHEMICAL): the particle size distribution was about 2 μm and about 10 μm, the average particle size was about 6 μm, and the refractive index was about 1.59.

(2) Solid styrene particles SBX17 (SEKISUI CHEMICAL): the particle size distribution was about 8 μm and about 28 μm, the average particle size was about 17 μm, and the refractive index was about 1.59.

Hollow Particles

(1) Hollow acrylic particles P50 of the Preparation Examples: the particle size distribution was about 0.01 μm and about 60 μm, the average particle size was about 14 and the refractive index of the shell was about 1.49.

(2) Hollow acrylic particles P90 of the Preparation Examples: the particle size distribution was about 0.01 μm and about 90 μm, and the refractive index of the shell was about 1.49.

(3) Hollow acrylic particles P150 of the Preparation Examples: the particle size distribution was about 0.01 μm and about 150 μm, and the refractive index of the shell was about 1.49.

The uniformly dispersed solution was coated on the substrate polyethylene terephthalate (PET) with a thickness of 188 μm of Toyobo by wet coating and the solvent was removed at 100° C. for several minutes to produce a light-extraction element. The ratio of the resin to the first particle and the second particle and the optical properties of the Comparative Examples and the Examples are as shown in Table 1 and Table 2. The configuration of the light-extraction element and the OLED device and the measurement of the light-extraction efficiency are described below.

[Measurement of the Light-Extraction Efficiency]

In each example, different light-extraction elements were adhered on the light-emitting surface of the commercially available Konica Minolta Symfos OLED light-emitting element by Amctape optical adhesive (OTA-050 propylene adhesive, the thickness was 50 μm, the refractive index was 1.478), and their different light extraction efficiencies were compared. A pure OLED device without a light-extraction element was taken as a Comparative Example. The brightness gain value and the change of the color shift during a viewing angle of 0-60° of the light-emitting element adhered with a light-extraction element were measured and calculated by a luminance meter (Topcon BM-7).

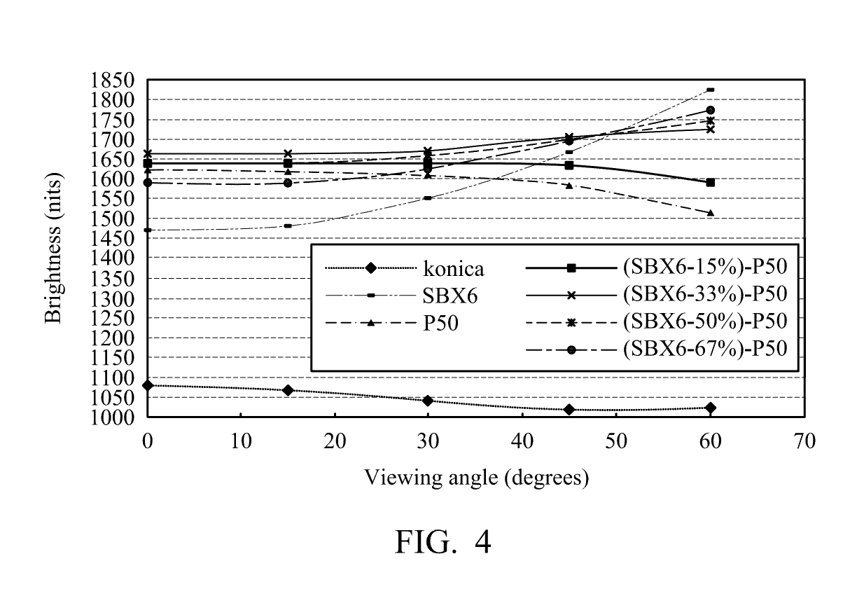

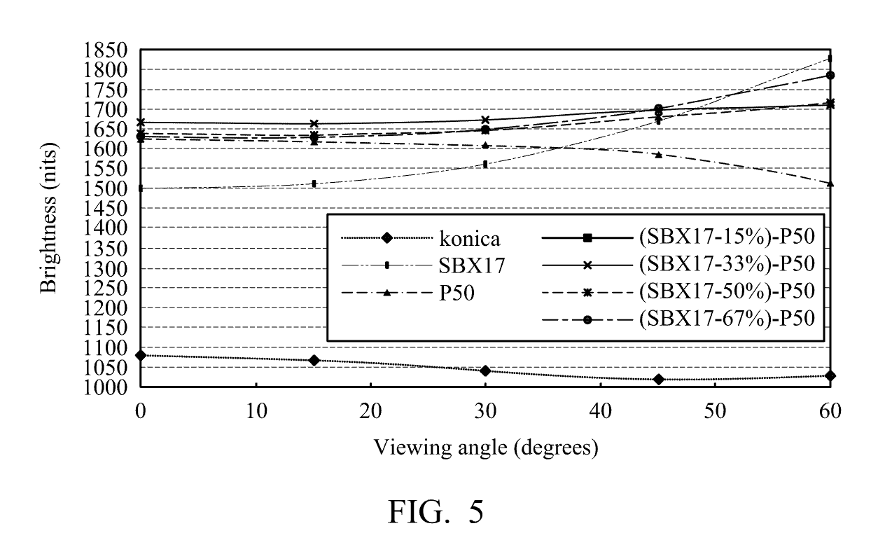

The particle composition of different light-diffusion layers and optical properties of the overall OLED elements which change with the particle ratios are shown in Table 1 and Table 2. In Table 1 and Table 2, the larger overall light-extraction efficiency the better, and the minor change of color shift (Δu‘v’) the better. The recited “Konica” in the Comparative Example 1 in Table 1 and Table 2 refers to the commercially available Konica Minolta Symfos OLED light-emitting element. The other data shown in Table 1 and 2 were obtained by measuring the commercially available Konica Minolta Symfos OLED light-emitting element adhered with the light-extraction element of Examples and Comparative Examples. FIG. 4 shows the brightness change of the light-extraction element including different particle compositions where the materials of the light-diffusion layer were composed of the solid particles SBX6 and the hollow particles P50. FIG. 5 shows the brightness change of the light-extraction element including different particle compositions where the materials of the light-diffusion layer were composed of the solid particles SBX17 and the hollow particles P50.

The results reveal that using hollow particles (P50) and solid particles (SBX6 or SBX17) as light-diffusion particles of the light-diffusion layer can make higher light-extraction efficiency than using a single particle type. Moreover, the light-diffusion layer mixing two particle-types can also make up the shortcoming of the inadequate ability of reducing the color shift using solid particles. The results of the Examples can prove that using hollow particles and solid particles as a particle composition of the light-diffusion layer can not only enhance the light-extraction efficiency but also reduce the color shift of OLEDs. In accordance with FIG. 4 and FIG. 5, the brightness of the pure solid particles becomes greater with the increase of the viewing angle. However, the mixture of the solid and hollow particles can not only enhance the overall light-extraction efficiency but also reduce the difference of brightness during different viewing angles.

TABLE 1
Diffusion particles: Solid particles SBX6 and hollow particles P50

| | | | Overall | |
|---|---|---|---|---|
| | | SBX6/ | light- | |
| | | total | extraction | |
| | | particles | efficiency | Color shift |
| Examples | Resin-Particle | (wt %) | (%) | (Δu‘v’) |
| Comparative | Konica | | | 0.0211 |
| Example 1 | | | | |
| Comparative | MCL_1-P50 | 0 | 52.10 | 0.0018 |
| Example 2 | | | | |
| Comparative | MCL_1-P90 | 0 | 37.66 | 0.0058 |
| Example 3 | | | | |
| Comparative | MCL_1-P150 | 0 | 34.30 | 0.0074 |
| Example 4 | | | | |
| Comparative | MCL_1-SBX6 | 100 | 48.85 | 0.0093 |
| Example 5 | | | | |
| Example 1 | MCL_1-(SBX6 + P50) | 15 | 56.00 | 0.0039 |
| Example 2 | MCL_1-(SBX6 + P50) | 33 | 61.42 | 0.0038 |
| Example 3 | MCL_1-(SBX6 + P50) | 50 | 60.33 | 0.0055 |
| Example 4 | MCL_1-(SBX6 + P50) | 67 | 58.27 | 0.0070 |

TABLE 2
Diffusion particles: Solid particles SBX17 and hollow particles P50

| | | | Overall | |
|---|---|---|---|---|
| | | SBX17/ | light- | |
| | | total | extraction | |
| | | particles | efficiency | Color shift |
| Examples | Resin-Particle | (wt %) | (%) | (Δu‘v’) |
| Comparative | Konica | | | 0.0211 |
| Example 1 | | | | |
| Comparative | MCL_1-P50 | 0 | 52.10 | 0.0018 |
| Example 2 | | | | |
| Comparative | MCL_1-SBX17 | 100 | 55.32 | 0.0097 |
| Example 6 | | | | |
| Example 5 | MCL_1-(SBX17 + P50) | 15 | 55.56 | 0.0042 |
| Example 6 | MCL_1-(SBX17 + P50) | 33 | 60.79 | 0.0045 |
| Example 7 | MCL_1-(SBX17 + P50) | 5 | 59.02 | 0.0063 |
| Example 8 | MCL_1-(SBX17 + P50) | 67 | 60.50 | 0.0075 |

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A light-extraction element, comprising:
a light-diffusion layer, the light-diffusion layer comprising:
a resin;
a first particle with a single refractive index; and
a second particle with two different refractive indices, wherein the second particle is a hollow particle or a core-shell particle, having different refractive indices between core and shell.

2. The light-extraction element as claimed in claim 1, wherein a refractive index of the first particle is different from that of the resin, and a refractive index of the shell of the second particle is different from that of the resin.

3. The light-extraction element as claimed in claim 1, wherein a particle size distribution of each of the first and second particles is between 0.01 μm and 150 μm.

4. The light-extraction element as claimed in claim 1, wherein each of the first and second particles is an independently spherical particle, hemispherical particle, rod-like particle, lens-like particle, irregular-shaped particle, or combinations thereof.

5. The light-extraction element as claimed in claim 1, wherein the ratio of the total weight of the first and second particles to the weight of the resin is between 1/10 and 10/1.

6. The light-extraction element as claimed in claim 1, wherein the resin comprises a thermoplastic resin, a thermo-curable resin, a light-curable resin, or combinations thereof.

7. The light-extraction element as claimed in claim 1, wherein the material of each of the first and second particles independently comprises polystyrene, polymethacrylic ester, copolymers of methyl methacrylate and styrene, polycarbonate, polyethylene, silicone resin, calcium carbonate, silica dioxide, titanium dioxide, or combinations thereof.

8. The light-extraction element as claimed in claim 1, wherein the resin covers the first and second particles and forms a flat top surface.

9. The light-extraction element as claimed in claim 1, wherein the resin covers the first and second particles and forms an irregular top surface.

10. The light-extraction element as claimed in claim 1, further comprising a substrate, and the light-diffusion layer is disposed on the substrate.

11. The light-extraction element as claimed in claim 10, further comprising an adhesion layer which is disposed on an opposite surface of the substrate relative to the light-diffusion layer.

12. The light-extraction element as claimed in claim 11, wherein the adhesion layer comprises a transparent glue including polypropylene, a thermo-curable glue, or an ultraviolet light-curable glue.

13. The light-extraction element as claimed in claim 1, further comprising an additive including one or more non-ionic dispersants, one or more surfactants, or combinations thereof.

14. The light-extraction element as claimed in claim 13, wherein the ratio of the additive is 0.005-15 wt % based on the total weight of the first and second particles.

15. A light-emitting device, comprising:
a pair of electrodes composed of an anode and a cathode;
an organic light-emitting unit disposed between the pair of electrodes, wherein the organic light-emitting unit comprises a light-emitting layer; and
a light-extraction element as claimed in claim 1, which is disposed on a light-emitting surface of the light-emitting device.

16. The light-emitting device as claimed in claim 15, wherein the organic light-emitting unit further comprises:
a hole injection layer disposed on the anode;
a hole transport layer disposed on the hole injection layer;
an electron transport layer disposed on the hole transport layer; and
an electron injection layer disposed on the electron transport layer and under the cathode.
